(19) United States
(12) Patent Application Publication
(10) Pub. No.: US 2017/0288239 A1
(43) Pub. Date: Oct. 5, 2017

(54) VENTED POWER SYSTEM RETROFIT

(71) Applicant: ALTERGY SYSTEMS, Folsom, CA (US)

(72) Inventor: Mark A. Wilkie, Diamond Springs, CA (US)

(73) Assignee: ALTERGY SYSTEMS, Folsom, CA (US)

(21) Appl. No.: 15/476,530

(22) Filed: Mar. 31, 2017

Related U.S. Application Data
(60) Provisional application No. 62/317,173, filed on Apr. 1, 2016.

(51) Int. Cl. H01M 8/04014; H05K 7/20; H05K 5/02

(52) U.S. Cl. CPC H01M 8/04014; H05K 5/0213; H05K 7/20909; H05K 5/0239

(57) ABSTRACT

A power generator replacement for an electrical system in an enclosure, where the power generator (e.g. a fuel cell, or the like), can be placed into an existing enclosure to replace a battery or bank of batteries which have been removed, while not disrupting the cooling airflow for the electrical system when the power generator is operated once the retrofit of the system has been completed.

### CROSS-REFERENCE TO RELATED APPLICATIONS

This application claims priority to, and the benefit of, U.S. provisional patent application Ser. No. 62/317,173 filed on Apr. 1, 2016, incorporated herein by reference in its entirety.

### STATEMENT REGARDING FEDERALLY SPONSORED RESEARCH OR DEVELOPMENT

Not Applicable

### INCORPORATION-BY-REFERENCE OF COMPUTER PROGRAM APPENDIX

Not Applicable

### NOTICE OF MATERIAL SUBJECT TO COPYRIGHT PROTECTION

A portion of the material in this patent document may be subject to copyright protection under the copyright laws of the United States and of other countries. The owner of the copyright rights has no objection to the facsimile reproduction by anyone of the patent document or the patent disclosure, as it appears in the United States Patent and Trademark Office publicly available file or records, but otherwise reserves all copyright rights whatsoever. The copyright owner does not hereby waive any of its rights to have this patent document maintained in secrecy, including without limitation its rights pursuant to 37 C.F.R. §1.14.

### BACKGROUND

### 1. Technical Field

The technology of this disclosure pertains generally to power systems, and more particularly to a retrofit for a vented power system.

### 2. Background Discussion

Remotely located electrical systems will often be mounted in weather-proof outdoor enclosures, utilizing grid electrical power as a primary power source. For critical applications, this primary source of grid power will often be augmented with a backup power source, such as batteries. In some cases, when the batteries cannot provide sufficient backup power for an extended time, an additional generator set with a fuel tank is sited next to the system. Because batteries often have short service lives or are otherwise unreliable, there is significant motivation to replace batteries with more attractive sources of backup power.

As alternative sources of electrical power generation such as fuel cells become more competitive relative to batteries, it becomes economically viable to replace batteries with fuel cells in backup power applications. An additional advantage is that the fuel cell system can often provide capabilities for longer backup power duration than batteries, eliminating the need for a separate generator and fuel tank external to the remote electrical system. However, in many existing systems (particularly those with a long field service life), the replacement of the batteries with a fuel cell can be problematic, unless the entire system is itself replaced. This is because most systems of this type will have either natural or forced air flow cooling systems for the electrical equipment, and the replacement of batteries located in the interior of an outdoor enclosure with a fuel cell creates problems. This is primarily due to the high airflow requirements for operating the fuel cell, since this air flow can disrupt the carefully engineered cooling airflow for the electrical equipment in the enclosure.

Furthermore, since it can be quite costly to remove and replace the enclosure with a new one, there exists a need to both install the fuel cell so that the fuel cell air flow does not interfere with the electrical equipment cooling air flow, while also utilizing (as much as possible) the original cabinet fixed in its original location to save cost.

### BRIEF SUMMARY

The present description is directed to a power generator replacement for an electrical system in an enclosure, where the power generator (e.g. a fuel cell, or the like), can be placed into an existing enclosure to replace a battery or bank of batteries which have been removed, while not disrupting the cooling airflow for the electrical system when the power generator is operated once the retrofit of the system has been completed.

In performing a retrofit of an enclosure containing a battery or bank of batteries and electrical equipment, at least two new vents are retrofitted into the enclosure: one for power generator intake air, and at least one for air/exhaust exiting the power generator. By sealing and isolating the airflow of the newly added vents, the power generator may operate without negatively affecting the air flow for the electrical equipment for the enclosure. The retrofit therefore comprises the steps of removing some or all of the batteries, clearing space, if needed, by cutting away certain interior parts, and adding vents to the enclosure sheet metal (preferably the front door), after which the power generator may be installed so that it seals at the vent openings. This seal may be accomplished, for example, with a gasket.

Further aspects of the technology described herein will be brought out in the following portions of the specification, wherein the detailed description is for the purpose of fully disclosing preferred embodiments of the technology without placing limitations thereon.

### BRIEF DESCRIPTION OF THE SEVERAL VIEWS OF THE DRAWING(S)

The technology described herein will be more fully understood by reference to the following drawings which are for illustrative purposes only:

FIG. 1 shows a typical existing vented power system with external generator and fuel tank.

FIG. 2 is a view of a vented power system and enclosure of FIG. 1 prior to retrofit modification.

FIG. 3 is a perspective view showing the enclosure and interior of a retrofitted vented power system in accordance with the present description.

FIG. 4 is a perspective view of the retrofitted vented power system of FIG. 1 with the enclosure door closed to show the exterior of the enclosure.

### DETAILED DESCRIPTION

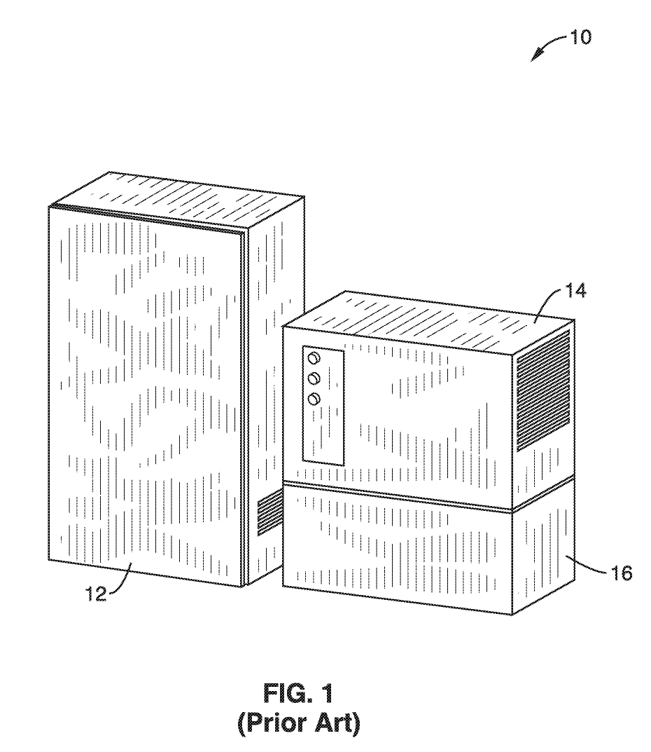

FIG. 1 shows a vented power system 10 comprising a power generation unit 12 and corresponding enclosure commonly available in the art. Vented power system 10 will often require an extended backup power source, such as an external generator 14, shown in FIG. 1 on top of an external generator fuel tank 16.

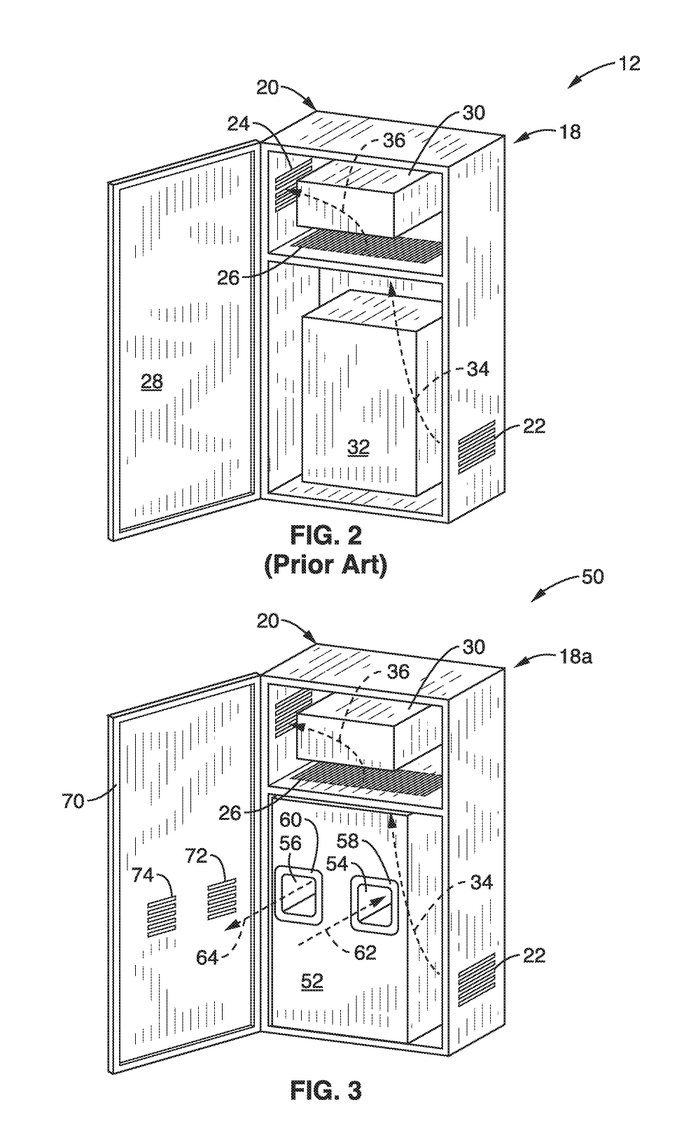

FIG. 2 shows a perspective view of the vented power system enclosure 18 of FIG. 1 prior to retrofit modification. Enclosure 18 comprises an enclosure cabinet 20 with hinged enclosure door 28, battery or battery bank 32, and electrical equipment 30. The enclosure 18 will generally comprise an existing airflow management structure for providing cooling air to the electrical equipment 30. Cooling air 34 is drawn in by natural or forced convection through electrical equipment cooling air intake vent 22 in cabinet 20. Cooling air 34 receives waste heat from electrical equipment 30 and leaves the enclosure as electrical equipment exhaust air 36 through electrical equipment exhaust air vent 24 in enclosure cabinet 20. An optional vented tray 26 may be disposed between the battery compartment and electrical equipment compartment to allow passage of cooling air 34.

FIG. 3 is shows a perspective view of a modified enclosure 18a and interior of a retrofitted vented power system 50 in accordance with the present description. In this configuration, the power source (e.g. battery bank 32) is replaced with an alternative power generator 52 (e.g. one or more fuel cells) to provide enhanced power application as well as longer power duration, eliminating the need for a separate generator and fuel tank external to the remote electrical system. Upon removal of some or all of the battery or battery bank 32, additional space inside modified enclosure 18a is provided. This removal may include, in some cases, physically cutting certain parts which may be welded to power system enclosure cabinet 20, and which cannot be effectively removed by other means. As shown in FIG. 3, this space is filled with power generator 52, which serves to replace battery or battery bank 32 from FIG. 2, as a source of power in modified enclosure 18a. The power generator 52 may be selected from a variety of power generating devices such as a piston engine generator, microturbine, thermoelectric generator, and the like, but is most preferably an electrochemical fuel cell.

In the configuration of a power generator 52 comprising an electrochemical fuel cell, the source of fuel (not shown) may also be included as part of the power generator shown as power generator 52. Fuel may also be positioned separately in cabinet 20. Viable sources of fuel include liquid fuels such as methanol, which may be converted to hydrogen with the use of a reformer, or directly converted in utilizing a direct methanol fuel cell. Another source of fuel may be hydrogen, stored as either compressed gas, a liquid, or hydrogen stored in a chemical hydride containing vessel. Sources of fuel may also be provided external to modified enclosure 18a (not shown).

As shown in FIG. 3, the power generator 52 will have an air intake 54 and at least one exhaust port 56 used in operation of the power generator 52 to generate power. For example, exhaust port 56 may comprise exhaust from a piston engine generator and exit radiator airflow (exhaust airflow) 64 mixed together in a common exhaust port. In an embodiment where the power generator 52 comprises a fuel cell, exhaust port 56 will facilitate the exhaust or exit airflow 64 from the fuel cell for removing waste heat from the fuel cell, with air intake 54 allowing intake airflow 62 in the form of one or more of process oxidizer and/or cooling air for operation the fuel cell 52. A modified enclosure door 70 is provided that comprises vents 72 and 74 to allow for air egress and ingress from the exhaust port 56 and air intake port 54, respectively. For purpose of this disclosure, a “door” may comprise any removable panel within the modified enclosure 18a, whether hinged, non-hinged, or using another form of attachment.

The existing venting airflow and path (e.g. cooling airflow 34 and exhaust airflow 36) will remain unchanged for the modified enclosure 18a, thus effectively providing cooling air to the electrical equipment 30. Cooling air 34 is drawn in by natural or forced convection through electrical equipment cooling air intake vent 22 in cabinet 22. Cooling air 34 receives waste heat from electrical equipment 30 and leaves the enclosure as electrical equipment exhaust air 36 through electrical equipment exhaust air vent 24 in enclosure cabinet 20. The optional vented tray 26 may be disposed between the battery compartment and electrical equipment compartment to allow passage of cooling air 34.

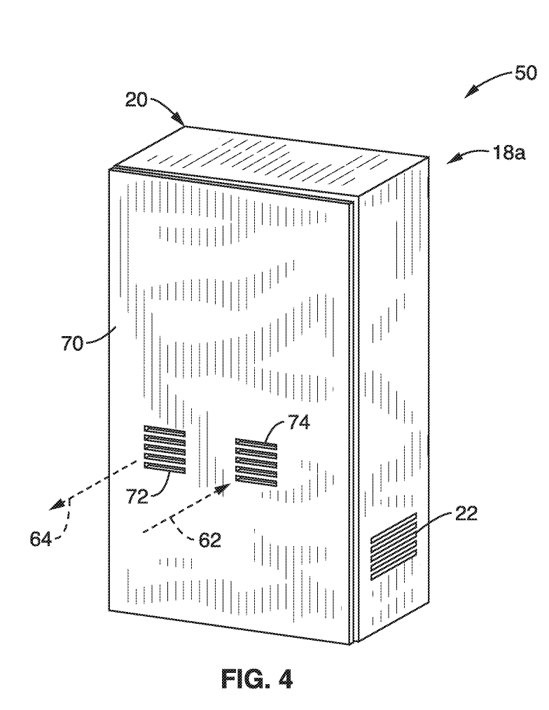

FIG. 4 illustrates a perspective view of the retrofitted vented power system 50 with the enclosure door 70 closed to show the exterior of the enclosure. As shown in FIG. 4, intake airflow (ambient inlet air) 62 enters modified vented enclosure 18a through power generator intake vent 74, while power generator exhaust airflow 64 exits the through power generator exhaust vent 72. As shown in FIG. 3 and FIG. 4, the power generator intake vent 74 and power generator exhaust vent 72 are positioned on the modified enclosure door 70 to line up with air intake 54 and exhaust port 56, respectively, of the power generator 52 when modified enclosure door 70 is closed as shown in FIG. 4.

In a preferred embodiment, an air intake gasket 58 and exhaust gasket 60 (FIG. 3) may be provided to seal against the modified enclosure door 70 when it is in the closed configuration as shown in FIG. 4. This ensures that intake airflow 62 and power generator exhaust airflow 64 will not communicate with or interfere with cooling air flow 34 and electrical equipment exhaust air 36. The air intake gasket 58 and exhaust gasket 60 are shown coupled to the power generator 52 in FIG. 3. Air intake gasket 58 and exhaust gasket 60 may also be integrated as a single gasket (not shown). It is also appreciated that air intake gasket 58 and exhaust gasket 60 may also be positioned on inside of door 70 around corresponding vents 74, 72. It is also appreciated that the door 70 and power generator 52 may be sized and positioned such that the door is in contact with the generator 52 at the air intake 54 and exhaust port 56, such that a seal is created without the need for gaskets.

A key feature of the modified enclosure 18a is that the intake airflow 62 and exhaust airflow 64 have ingress/egress into the modified enclosure 18a via airflows that are substantially isolated from, and do not substantially mix or integrate with, the existing venting airflow of the enclosure (e.g. airflows 34 and 36). For example, heated exhaust airflow 64 exits the enclosure without mixing with cooling air 34, thus not having the affect of heating the cooling air 34 prior to it entering the equipment 30 compartment.

While the intake airflow 62 is shown in FIG. 4 to enter modified enclosure 18a through power generator intake vent 74, and power generator exhaust airflow 64 is shown to leave through power generator exhaust vent 72, it is appreciated that other embodiments may also be considered. Alternative or additional vents (not shown) may be made in enclosure cabinet 20, such that intake airflow 62 or power generator exhaust airflow 64 will enter exit a modified enclosure 18a through vents which are not located on the enclosure door 70. In this configuration, one or more panels of the cabinet 20 may be exchanged with one or more panels (not shown) having vents or otherwise fit with vents. Air intake 54 and exhaust port 56 of the power generator would thus be located to face the replaced panel.

It is appreciated that the retrofitted vented power system 50 of FIG. 3 and FIG. 4 does not require the external generator 14 or fuel tank 16, saving further cost, because power generator 52, when configured as a fuel cell (for example), may have a significantly higher backup power capability compared to battery or battery bank 32.

From the description herein, it will be appreciated that that the present disclosure encompasses multiple embodiments which include, but are not limited to, the following:

1. A retrofit assembly for modifying a power source of a vented power system, the vented power system comprising an enclosure comprising a cabinet for containing the power source and heat-generating electrical equipment, and an enclosure door attached to the enclosure, wherein the enclosure comprises an existing venting structure to generate a venting airflow to cool said electrical equipment, the retrofit assembly comprising: a power generator configured to replace at least a portion of the power source and be positioned in the enclosure in place of said removed power source; said power generator comprising an air intake and exhaust; an intake vent positioned within the enclosure at a location adjacent the air intake of the positioned power generator to provide an intake airflow from the intake air vent to the air intake of the power generator; an exhaust vent positioned within the enclosure at a location adjacent the exhaust of the positioned power generator to provide an exhaust air flow from the exhaust of the power generator to the exhaust vent; and wherein both the exhaust airflow and intake airflow are independent of, and isolated from, the venting airflow of the enclosure such that the exhaust airflow and air intake airflow do not substantially disturb or modify the venting airflow or airflow path.

2. The retrofit assembly of any proceeding embodiment, further comprising: one or more sealing structures positioned at the intake vent and the exhaust vent; wherein the one or more sealing structures are configured to seal the interface between the intake vent and the air intake and between the exhaust vent and the exhaust of the power generator to restrict intake airflow and exhaust airflow from communicating with venting airflow within the enclosure.

3. The retrofit assembly of any proceeding embodiment, wherein the existing venting structure comprises an equipment cooling air intake vent and an equipment cooling exhaust vent to generate the venting airflow within at least a portion of the enclosure.

4. The retrofit of any proceeding embodiment: wherein said power source comprises one or more batteries; and wherein the power generator is configured to replace one or more of said batteries upon removal of said one or more batteries.

5. The retrofit assembly of any proceeding embodiment, further comprising: a retrofit enclosure door configured to be installed in place of the enclosure door; wherein the intake vent is positioned on the retrofit enclosure door such that the intake vent is adjacent the air intake of the power generator when the retrofit enclosure door is in a closed position with respect to the enclosure cabinet; and wherein the exhaust vent is positioned on the retrofit enclosure door such that the exhaust vent is adjacent the exhaust of the power generator when the retrofit enclosure door is in a closed position with respect to the enclosure cabinet.

6. The retrofit assembly of any proceeding embodiment, wherein said one or more sealing structures comprise at least one sealing gasket positioned at the intake vent and the exhaust vent; wherein closure of the retrofit enclosure door is configured to compress the at least one sealing gasket to substantially prevent leakage of said exhaust airflow and intake airflow into the enclosure.

7. The retrofit assembly of any proceeding embodiment, further comprising: a retrofit enclosure panel configured to be installed in place a panel of the enclosure cabinet; wherein the intake vent is positioned on the installed retrofit enclosure panel such that the intake vent is adjacent the air intake of the power generator; and wherein the exhaust vent is positioned on the installed retrofit enclosure panel such that the exhaust vent is adjacent the exhaust of the power generator.

8. The retrofit assembly of any proceeding embodiment, wherein the power generator comprises an electrochemical fuel cell.

9. A retrofit assembly for modifying a power source of a vented power system, the vented power system comprising an enclosure comprising a cabinet for containing the power source and heat-generating electrical equipment, and an enclosure door attached to the enclosure, wherein the enclosure comprises an existing venting structure to generate a venting airflow to cool said electrical equipment, the retrofit assembly comprising: a power generator configured to replace at least a portion of the power source and be positioned in the enclosure in place of said power source; said power generator comprising an air intake and exhaust; and a retrofit enclosure door configured to be installed in place of the enclosure door; an intake vent positioned on the retrofit enclosure door such that the intake vent is adjacent the air intake of the power generator when the retrofit enclosure door is in a closed position with respect to the enclosure cabinet to provide an intake airflow from the intake vent to the air intake of the power generator; an exhaust vent positioned on the retrofit enclosure door such that the exhaust vent is adjacent the exhaust of the power generator when the retrofit enclosure door is in a closed position with respect to the enclosure cabinet to provide an exhaust air flow from the exhaust of the power generator to the exhaust vent; wherein both the exhaust airflow and intake airflow are independent of, and isolated from, the venting airflow of the enclosure such that the exhaust airflow and air intake airflow do not to substantially disturb or modify the venting airflow or airflow path.

10. The retrofit assembly of any proceeding embodiment, further comprising: one or more sealing structures positioned at the intake vent and the exhaust vent; wherein the one or more sealing structures are configured to seal the interface between the intake vent and the air intake and between the exhaust vent and the exhaust of the power generator to restrict intake airflow and exhaust airflow from communicating with venting airflow within the enclosure.

11. The retrofit assembly of any proceeding embodiment, wherein the existing venting structure comprises an equipment cooling air intake vent and an equipment cooling exhaust vent to generate the venting airflow within at least a portion of the enclosure.

12. The retrofit assembly of any proceeding embodiment: wherein said power source comprises one or more batteries; and wherein the power generator is configured to replace one or more of said batteries upon removal of said one or more batteries.

13. The retrofit assembly of any proceeding embodiment, wherein said one or more sealing structures comprise at least one sealing gasket positioned at the intake vent and the exhaust vent; and wherein closure of the retrofit enclosure door is configured to compress the at least one sealing gasket to substantially prevent leakage of said exhaust airflow and intake airflow into the enclosure.

14. The retrofit assembly of any proceeding embodiment, wherein the power generator comprises an electrochemical fuel cell.

15. A method for modifying a power source of a vented power system, the vented power system comprising an enclosure comprising a cabinet for containing the power source and heat-generating electrical equipment, and an enclosure door attached to the enclosure, wherein the enclosure comprises an existing venting structure to generate a venting airflow to cool said electrical equipment, the method comprising: removing at least a portion of the power source from the enclosure; positioning a power generator configured to provide an alternative source of power to the power system in a location previously occupied by the removed power source; said power generator comprising an air intake and exhaust; positioning an intake vent within the enclosure at a location adjacent the air intake of the positioned power generator to provide an intake airflow from the intake air vent to the air intake of the power generator; positioning an exhaust vent within the enclosure at a location adjacent the exhaust of the positioned power generator to provide an exhaust air flow from the exhaust of the power generator to the exhaust vent; wherein both the exhaust airflow and intake airflow are independent of, and isolated from, the venting airflow of the enclosure such that the exhaust airflow and air intake airflow do not substantially disturb or modify the venting airflow or airflow path.

16. The method of any proceeding embodiment, further comprising: positioning one or more sealing structures at the intake vent and the exhaust vent; sealing the interface between the intake vent and the air intake and between the exhaust vent and the exhaust of the power generator to restrict intake airflow and exhaust airflow from communicating with venting airflow within the enclosure.

17. The method of any proceeding embodiment, further comprising: installing a retrofit enclosure door configured in place of the enclosure door; positioning the intake vent on the retrofit enclosure door such that the intake vent is adjacent the air intake of the power generator when the retrofit enclosure door is in a closed position with respect to the enclosure cabinet; and positioning the exhaust vent on the retrofit enclosure door such that the exhaust vent is adjacent the exhaust of the power generator when the retrofit enclosure door is in a closed position with respect to the enclosure cabinet.

18. The method of any proceeding embodiment, wherein said one or more sealing structures comprise at least one sealing gasket positioned at the intake vent and the exhaust vent; wherein closure of the retrofit enclosure door is configured to compress the at least one sealing gasket to substantially prevent leakage of said exhaust airflow and intake airflow into the enclosure.

19. The method of any proceeding embodiment, further comprising: installing a retrofit enclosure panel in place a panel of the enclosure cabinet; positioning the intake vent on the installed retrofit enclosure panel such that the intake vent is adjacent the air intake of the power generator; and positioning the exhaust vent on the installed retrofit enclosure panel such that the exhaust vent is adjacent the exhaust of the power generator.

20. The method of any proceeding embodiment, wherein the power generator comprises an electrochemical fuel cell.

21. A vented power system retrofit comprising: an original enclosure containing at least a battery or a bank of batteries, and electrical equipment which requires cooling, where the original enclosure has at least one intake air opening or vent and at least one air exit opening or vent effective to allow the passage of cooling air to enter the original enclosure, cool said electrical equipment, and exit the original enclosure, a retrofit assembly for yielding a modified original enclosure, comprising at least a power generator with inlet air and heated exhaust, and parts for modifying the original enclosure to provide passage of the power generator inlet air and power generator heated exhaust into and out of a modified original enclosure, respectively, where some or all of said battery or bank of batteries are removed and replaced with said power generator, and said original enclosure is modified with parts to provide passage of the power generator inlet air and power generator heated exhaust into and out of a modified original enclosure, respectively, where said power generator is installed in sealing fashion such that the power generator inlet air flow into the modified original enclosure and power generator heated exhaust flow out of the modified original enclosure do not substantially affect the cooling air of the electrical equipment.

22. The vented power system retrofit of any preceding embodiment, where said original enclosure has a door or removable panel, and parts for modifying the original enclosure include a new or modified door or removable panel with openings to provide passage of the power generator inlet air and power generator heated exhaust into and out said modified original enclosure.

23. The vented power system retrofit of any preceding embodiment, where said original enclosure has a door or removable panel, and parts for modifying the original enclosure include a new or modified door or removable panel with openings to provide passage of the power generator inlet air and power generator heated exhaust into and out of said modified original enclosure, and closure of the new door or installation of the removable panel compresses at least one sealing gasket to substantially prevent leakage of said inlet air and heated exhaust into modified original enclosure.

24. The vented power system retrofit of any preceding embodiment, where the power generator comprises an electrochemical fuel cell.

25. A method for retrofitting an original enclosure containing at least a battery or a bank of batteries, and electrical equipment which requires cooling, where the original enclosure has at least one intake air opening or vent and at least one air exit opening or vent effective to allow the passage of cooling air to enter the original enclosure, cool said electrical equipment, and exit the original enclosure, comprising the following tasks: removing some or all of said battery or bank of batteries; removing remaining unneeded parts; replacing or modifying the original enclosure or parts thereof such that there is a passageway to the exterior of the modified enclosure for power generator inlet air and power generator heated exhaust, forming a modified original enclosure; installing a power generator into the interior of the modified original enclosure such that the power generator inlet air and power generator heated exhaust are substantially sealed from entering the interior of the modified original enclosure outside of the power generator, such that the passage of cooling air entering the modified original enclosure, cooling said electrical equipment, and exiting the modified original enclosure remains effective to cool said electrical equipment.

26. A vented power system retrofit comprising: an enclosure containing one or more batteries, and heat-generating electrical equipment, wherein the enclosure has at least one intake air opening or vent and at least one air exit opening or vent effective to allow the passage of cooling air to enter the original enclosure, cool said electrical equipment, and exit the enclosure, a retrofit assembly for modifying the enclosure, comprising a power generator with inlet air and heated exhaust, and parts for modifying the original enclosure to provide passage of the power generator inlet air and power generator heated exhaust into and out of a modified original enclosure, respectively; wherein said power generator is configured to replace some or all of said one or more batteries upon removal of said one or more batteries; wherein said original enclosure is modified with parts to provide passage of the power generator inlet air and power generator heated exhaust into and out of a modified original enclosure, respectively; said retrofit further comprising sealing components such that said power generator is installed in sealing fashion such that the power generator inlet air flow into the modified enclosure and power generator heated exhaust flow out of the modified enclosure do not substantially affect the cooling air of the electrical equipment.

27. The vented power system retrofit of any preceding embodiment, wherein said enclosure comprises a door or removable panel, said retrofit further comprising: a replacement or modified door or removable panel with openings to provide passage of the power generator inlet air and power generator heated exhaust into and out said modified enclosure.

28. The vented power system retrofit of any preceding embodiment, wherein said sealing components comprises at least one sealing gasket configured to be coupled to the power generator: wherein closure of the replacement door or installation of the removable panel is configured to compress the at least one sealing gasket to substantially prevent leakage of said inlet air and heated exhaust into modified original enclosure.

29. The vented power system retrofit of any preceding embodiment, wherein the power generator comprises an electrochemical fuel cell.

30. A vented power system retrofit assembly for modifying an enclosure containing one or more batteries and heat-generating electrical equipment, wherein the enclosure has at least one intake air opening or vent and at least one air exit opening or vent effective to allow the passage of cooling air to enter the original enclosure, cool said electrical equipment, and exit the enclosure, the retrofit comprising: a power generator with inlet air and heated exhaust, and associated components for modifying the original enclosure to provide passage of the power generator inlet air and power generator heated exhaust into and out of a modified original enclosure, respectively; wherein said power generator is configured to replace some or all of said one or more batteries upon removal of said one or more batteries; one or more venting components to provide passage of the power generator inlet air and power generator heated exhaust into and out of a modified original enclosure, respectively; and one or more sealing components configured such that said power generator is installed in sealing fashion such that the power generator inlet air flow into the modified enclosure and power generator heated exhaust flow out of the modified enclosure do not substantially affect the cooling air of the electrical equipment.

31. The vented power system retrofit assembly of any preceding embodiment, wherein said enclosure comprises a door or removable panel, said retrofit assembly further comprising: wherein the one or more venting components comprises a removable replacement panel comprising openings to provide passage of the power generator inlet air and power generator heated exhaust into and out said modified enclosure.

32. The vented power system retrofit assembly of any preceding embodiment, wherein said one or more sealing components comprises at least one sealing gasket configured to be coupled to the power generator: wherein closure of the removable replacement panel is configured to compress the at least one sealing gasket to substantially prevent leakage of said inlet air and heated exhaust into modified original enclosure.

33. The vented power system retrofit assembly of any preceding embodiment, wherein the power generator comprises an electrochemical fuel cell.

34. A method for modifying an enclosure containing one or more batteries and heat-generating electrical equipment, wherein the enclosure has at least one intake air opening or vent and at least one air exit opening or vent effective to allow the passage of cooling air to enter the original enclosure, cool said electrical equipment, and exit the enclosure, the method comprising: removing some or all of said one or more batteries; installing a power generator into the interior of the modified enclosure in place of the one or more removed batteries; the power generator positioned in the modified enclosure such that such that power generator inlet air and power generator heated exhaust are substantially sealed from entering the interior of the modified original enclosure outside of the power generator, such that the passage of cooling air entering the modified original enclosure, cooling said electrical equipment, and exiting the modified original enclosure remains effective to cool said electrical equipment.

35. The method of any preceding embodiment, further comprising: modifying the enclosure or parts thereof such that there is a passageway to the exterior of the modified enclosure for power generator inlet air and power generator heated exhaust, forming the modified original enclosure.

Although the description herein contains many details, these should not be construed as limiting the scope of the disclosure but as merely providing illustrations of some of the presently preferred embodiments. Therefore, it will be appreciated that the scope of the disclosure fully encompasses other embodiments which may become obvious to those skilled in the art.

In the claims, reference to an element in the singular is not intended to mean “one and only one” unless explicitly so stated, but rather “one or more.” All structural, chemical, and functional equivalents to the elements of the disclosed embodiments that are known to those of ordinary skill in the art are expressly incorporated herein by reference and are intended to be encompassed by the present claims. Furthermore, no element, component, or method step in the present disclosure is intended to be dedicated to the public regardless of whether the element, component, or method step is explicitly recited in the claims. No claim element herein is to be construed as a “means plus function” element unless the element is expressly recited using the phrase “means for”. No claim element herein is to be construed as a “step plus function” element unless the element is expressly recited using the phrase “step for”.

What is claimed is:

1. A retrofit assembly for modifying a power source of a vented power system, the vented power system comprising an enclosure comprising a cabinet for containing the power source and heat-generating electrical equipment, and an enclosure door attached to the enclosure, wherein the enclosure comprises an existing venting structure to generate a venting airflow to cool said electrical equipment, the retrofit assembly comprising:
a power generator configured to replace at least a portion of the power source and be positioned in the enclosure in place of said removed power source;
said power generator comprising an air intake and exhaust;
an intake vent positioned within the enclosure at a location adjacent the air intake of the positioned power generator to provide an intake airflow from the intake air vent to the air intake of the power generator;
an exhaust vent positioned within the enclosure at a location adjacent the exhaust of the positioned power generator to provide an exhaust air flow from the exhaust of the power generator to the exhaust vent; and
wherein both the exhaust airflow and intake airflow are independent of, and isolated from, the venting airflow of the enclosure such that the exhaust airflow and air intake airflow do not substantially disturb or modify the venting airflow or airflow path.

2. The retrofit assembly of claim 1, further comprising:
one or more sealing structures positioned at the intake vent and the exhaust vent;
wherein the one or more sealing structures are configured to seal the interface between the intake vent and the air intake and between the exhaust vent and the exhaust of the power generator to restrict intake airflow and exhaust airflow from communicating with venting airflow within the enclosure.

3. The retrofit assembly of claim 1, wherein the existing venting structure comprises an equipment cooling air intake vent and an equipment cooling exhaust vent to facilitate the venting airflow within at least a portion of the enclosure.

4. The retrofit assembly of claim 1:
wherein said power source comprises one or more batteries; and
wherein the power generator is configured to replace one or more of said batteries upon removal of said one or more batteries.

5. The retrofit assembly of claim 2, further comprising:
a retrofit enclosure door configured to be installed in place of the enclosure door;
wherein the intake vent is positioned on the retrofit enclosure door such that the intake vent is adjacent the air intake of the power generator when the retrofit enclosure door is in a closed position with respect to the enclosure cabinet; and
wherein the exhaust vent is positioned on the retrofit enclosure door such that the exhaust vent is adjacent the exhaust of the power generator when the retrofit enclosure door is in a closed position with respect to the enclosure cabinet.

6. The retrofit assembly of claim 5:
wherein said one or more sealing structures comprise at least one sealing gasket positioned at the intake vent and the exhaust vent; and
wherein closure of the retrofit enclosure door is configured to compress the at least one sealing gasket to substantially prevent leakage of said exhaust airflow and intake airflow into the enclosure.

7. The retrofit assembly of claim 2, further comprising:
a retrofit enclosure panel configured to be installed in place a panel of the enclosure cabinet;
wherein the intake vent is positioned on the installed retrofit enclosure panel such that the intake vent is adjacent the air intake of the power generator; and
wherein the exhaust vent is positioned on the installed retrofit enclosure panel such that the exhaust vent is adjacent the exhaust of the power generator.

8. The retrofit assembly of claim 1, wherein the power generator comprises an electrochemical fuel cell.

9. A retrofit assembly for modifying a power source of a vented power system, the vented power system comprising an enclosure comprising a cabinet for containing the power source and heat-generating electrical equipment, and an enclosure door attached to the enclosure, wherein the enclosure comprises an existing venting structure to generate a venting airflow to cool said electrical equipment, the retrofit assembly comprising:
a power generator configured to replace at least a portion of the power source and be positioned in the enclosure in place of said power source;
said power generator comprising an air intake and exhaust;
a retrofit enclosure door configured to be installed in place of the enclosure door;
an intake vent positioned on the retrofit enclosure door such that the intake vent is adjacent the air intake of the power generator when the retrofit enclosure door is in a closed position with respect to the enclosure cabinet to provide an intake airflow from the intake vent to the air intake of the power generator; and
an exhaust vent positioned on the retrofit enclosure door such that the exhaust vent is adjacent the exhaust of the power generator when the retrofit enclosure door is in a closed position with respect to the enclosure cabinet to provide an exhaust air flow from the exhaust of the power generator to the exhaust vent;
wherein both the exhaust airflow and intake airflow are independent of, and isolated from, the venting airflow of the enclosure such that the exhaust airflow and air intake airflow do not to substantially disturb or modify the venting airflow or airflow path.

10. The retrofit assembly of claim 9, further comprising:
one or more sealing structures positioned at the intake vent and the exhaust vent;
wherein the one or more sealing structures are configured to seal the interface between the intake vent and the air intake and between the exhaust vent and the exhaust of the power generator to restrict intake airflow and exhaust airflow from communicating with venting airflow within the enclosure.

11. The retrofit assembly of claim 9, wherein the existing venting structure comprises an equipment cooling air intake vent and an equipment cooling exhaust vent to facilitate the venting airflow within at least a portion of the enclosure.

12. The retrofit assembly of claim 9:
wherein said power source comprises one or more batteries; and
wherein the power generator is configured to replace one or more of said batteries upon removal of said one or more batteries.

13. The retrofit assembly of claim 10:
wherein said one or more sealing structures comprise at least one sealing gasket positioned at the intake vent and the exhaust vent; and
wherein closure of the retrofit enclosure door is configured to compress the at least one sealing gasket to substantially prevent leakage of said exhaust airflow and intake airflow into the enclosure.

14. The retrofit assembly of claim 9, wherein the power generator comprises an electrochemical fuel cell.

15. A method for modifying a power source of a vented power system, the vented power system comprising an enclosure comprising a cabinet for containing the power source and heat-generating electrical equipment, and an enclosure door attached to the enclosure, wherein the enclosure comprises an existing venting structure to generate a venting airflow to cool said electrical equipment, the method comprising:
removing at least a portion of the power source from the enclosure;
positioning a power generator configured to provide an alternative source of power to the power system in a location previously occupied by the removed power source;
said power generator comprising an air intake and exhaust;
positioning an intake vent within the enclosure at a location adjacent the air intake of the positioned power generator to provide an intake airflow from the intake air vent to the air intake of the power generator; and
positioning an exhaust vent within the enclosure at a location adjacent the exhaust of the positioned power generator to provide an exhaust air flow from the exhaust of the power generator to the exhaust vent;
wherein both the exhaust airflow and intake airflow are independent of, and isolated from, the venting airflow of the enclosure such that the exhaust airflow and air intake airflow do not substantially disturb or modify the venting airflow or airflow path.

16. The method of claim 15, further comprising:
positioning one or more sealing structures at the intake vent and the exhaust vent; and
sealing the interface between the intake vent and the air intake and between the exhaust vent and the exhaust of the power generator to restrict intake airflow and exhaust airflow from communicating with venting airflow within the enclosure.

17. The method of claim 15, further comprising:
installing a retrofit enclosure door configured in place of the enclosure door;
positioning the intake vent on the retrofit enclosure door such that the intake vent is adjacent the air intake of the power generator when the retrofit enclosure door is in a closed position with respect to the enclosure cabinet; and
positioning the exhaust vent on the retrofit enclosure door such that the exhaust vent is adjacent the exhaust of the power generator when the retrofit enclosure door is in a closed position with respect to the enclosure cabinet.

18. The method of claim 17, wherein said one or more sealing structures comprise at least one sealing gasket positioned at the intake vent and the exhaust vent; and
wherein closure of the retrofit enclosure door is configured to compress the at least one sealing gasket to substantially prevent leakage of said exhaust airflow and intake airflow into the enclosure.

19. The method of claim 15, further comprising:
installing a retrofit enclosure panel in place a panel of the enclosure cabinet;
positioning the intake vent on the installed retrofit enclosure panel such that the intake vent is adjacent the air intake of the power generator; and
positioning the exhaust vent on the installed retrofit enclosure panel such that the exhaust vent is adjacent the exhaust of the power generator.

20. The method of claim 15, wherein the power generator comprises an electrochemical fuel cell.
